(19) United States
(12) Patent Application Publication
(10) Pub. No.: US 2021/0202400 A1
(43) Pub. Date: Jul. 1, 2021

(54) DISCRETE MAGNETIC SHIELDING SHEET

(71) Applicant: International Business Machines Corporation, Armonk, NY (US)

(72) Inventors: Xin Zhang, Chappaqua, NY (US); Todd Edward Takken, Brewster, NY (US); Naigang Wang, Ossining, NY (US)

(21) Appl. No.: 16/729,622

(22) Filed: Dec. 30, 2019

(51) Int. Cl. H01L 23/552; H01L 23/00; H01L 23/367; H01L 23/14; H01L 49/02

(52) U.S. Cl. CPC H01L 23/552; H01L 24/16; H01L 24/32; H01L 23/3675; H01L 23/145; H01L 2224/73203; H01L 28/10; H01L 2224/16225; H01L 2924/3025; H01L 2224/32245; H01L 24/73

(57) ABSTRACT

The structure includes a substrate. The structure includes a semiconductor chip connected to the substrate via on or more solder balls. The structure includes a magnetic shielding sheet located between the substrate and the semiconductor chip.

### BACKGROUND

The present invention relates generally to the field of semiconductor chips, and more particularly to a discrete magnetic shielding between a semiconductor chip and substrate.

An integrated circuit, also referred to as an IC, chip, or microchip, is a set or grouping of circuits located on a set piece of semiconductor material that is normally silicon. Integrated circuits have two main advantages over discrete circuits: cost and performance. Modern integrated circuits can employ any number of on-chip magnetic devices.

### SUMMARY

Embodiments of the present invention include a structure. In an embodiment, the structure includes a substrate. The structure includes a semiconductor chip connected to the substrate via on or more solder balls. The structure includes a magnetic shielding sheet located between the substrate and the semiconductor chip.

### BRIEF DESCRIPTION OF THE DRAWINGS

FIG. 1 is a pictorial representation (through a cross-sectional view) depicting a semiconductor chip including a magnetic device attached to a substrate with a discrete magnetic shield, in accordance with a first embodiment of the invention.

FIG. 2 is a pictorial representation (through a cross-sectional view) depicting a semiconductor chip including a magnetic device attached to a substrate with a discrete magnetic shield, in accordance with a second embodiment of the invention.

FIG. 3 is a pictorial representation (through a cross-sectional view) depicting a semiconductor chip including a magnetic device attached to a substrate with a discrete magnetic shield, in accordance with a third embodiment of the invention.

FIG. 4 is a pictorial representation (through a cross-sectional view) depicting a semiconductor chip including a magnetic device attached to a substrate with a discrete magnetic shield, in accordance with a fourth embodiment of the invention.

FIG. 5 is a pictorial representation (through a cross-sectional view) depicting a semiconductor chip including a magnetic device attached to a substrate with a discrete magnetic shield, in accordance with a fifth embodiment of the invention.

### DETAILED DESCRIPTION

Full integrated power converter semiconductor chips usually employ an on-chip magnetic device. When the converter is working. The magnetic device generates a magnetic field. If the converter is closely packaged with another device, in most cases the load of the converter, the magnetic field will cause interference with the electrical signals of the load device if the magnetic field is not shielded.

Embodiments of the present invention provide for a discrete magnetic shield between the semiconductor chip that includes the device causing the magnetic field and a substrate. Embodiments of the present invention provide for a discrete magnetic shield that stops and/or recues the magnetic field of the magnetic device on-chip.

Detailed description of embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present invention.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. The term non-crystalline refers to amorphous, nano-crystalline or micro-crystalline. The term crystalline refers to single-crystalline (i.e., mono-crystalline) or poly-crystalline (i.e., multi-crystalline).

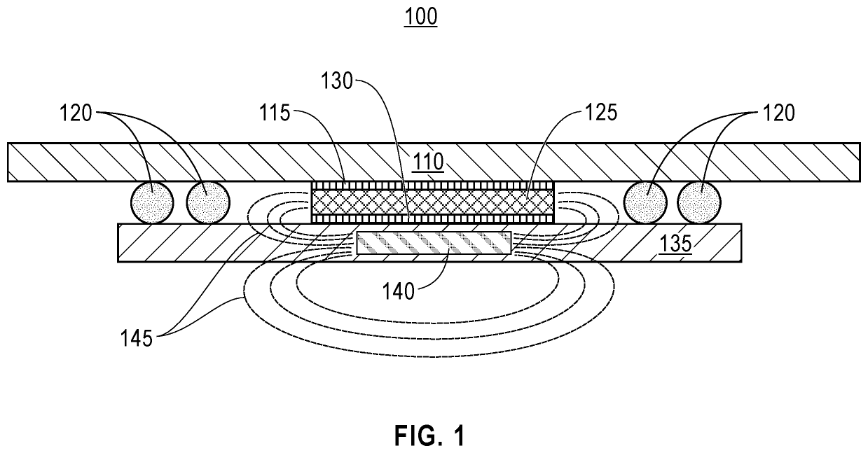

Reference is now made to FIGS. 1-5, which illustrate multiple embodiments of a structure consisting of a discrete magnetic shielding sheet between a semiconductor chip and a substrate.

Referring to Figure there is a pictorial representation (through a cross-sectional view) depicting a first embodiment of a structure 100 consisting of a discrete magnetic shielding sheet 125 between a semiconductor chip 135 and a substrate 110. FIG. 1 depicts a substrate 110 attached to semiconductor chip 135 via one or more solder ball(s) 120. In an embodiment, substrate 110 may be circuit board, mother board, or any other substrate known in the art to connect a semiconductor chip 135. In an embodiment, the substrate 110 may be an organic substrate. In an embodiment, substrate 110 may include the load (not shown) that powers the magnetic device 140. In an embodiment, one or more solder ball(s) 120 are used to attach the semiconductor chip 135 to the substrate 110. In an alternative embodiment, any other connecting structure or device known in the art may be used to connect the semiconductor chip 135 to the substrate 110.

FIG. 1 depicts a semiconductor chip 135 that includes magnetic device 140. In an embodiment, semiconductor chip 135 is a fully integrated power converter semiconductor chip. In an embodiment, semiconductor chip 135 employs an on-chip magnetic device 140. In an embodiment, the on-chip magnetic device 140 may be an on-chip inductor or an on-chip transformer, which composes of on-chip metal windings. In an alternative embodiment, the on-chip magnetic device 140 may be an on-chip inductor or an on-chip transformer, which composes of on-chip metal windings and magnetic cores. In an embodiment, the on-chip magnetic device 140 may be more than one on-chip magnetic device 140. In an embodiment, when a current is passed through the on-chip magnetic device 140 a magnetic field 145 is created. The magnetic field 145 may interact with other devices (not shown) that may or may not be connected to substrate 110.

In a first embodiment, as shown in FIG. 1, a discrete magnetic shield 125 is located between the substrate 110 and semiconductor chip 135. In the first embodiment, the discrete magnetic shield 125 is attached to a first side of substrate 110 using adhesive layer 115. In the first embodiment, the discrete magnetic shield 125 is attached to a first side of the semiconductor chip 135 using adhesive layer 130. In an embodiment, the adhesive layer 115 and adhesive layer 130 may be an adhesive that is thermal conductive, and non-magnetic and non-electrically conductive. For example, adhesive layer 115 and adhesive layer 130 may be CoolTherm® ME-560 Underfill Encapsulant. In an embodiment, the adhesive layer 115 and adhesive layer 130 may be a thermal conductive glue. In an embodiment, the thermal conductive glue may create a thermal path between the semiconductor chip 135 and the substrate 110 via the discrete magnetic shield 125. In an embodiment, the discrete magnetic shield 125 prevents magnetic field 145 from penetrating into substrate 110. In an embedment, the discrete magnetic shield 125 may also be called a magnetic shielding sheet. In an embodiment, the magnetic shield 125 may be a magnetic core, for example, a magnetic piece made of ferromagnetic metal, such as iron, or ferrimagnetic compounds such as ferrites. In an embodiment, the magnetic shield 125 may be from a machined magnetic material. In an embodiment, the magnetic shield 125 may be the same lateral area of the magnetic device 140. In an alternative embodiment, the magnetic shield 125 may be a smaller lateral area of the magnetic device 140. In yet another alternative embodiment, the magnetic shield 125 may be a larger lateral area of the magnetic device 140, for example twice the surface area. In an embodiment, the magnetic shield 125 is smaller in thickness than the one or more solder ball(s) 120. For example, if the one or more solder ball(s) 120 is 75 micrometers (um) in height, then the magnetic shield 125 may be 40-50 um thick. In an embodiment, the magnetic shield 125 is thinner than the post-assembly height of the one or more solder ball(s) 120.

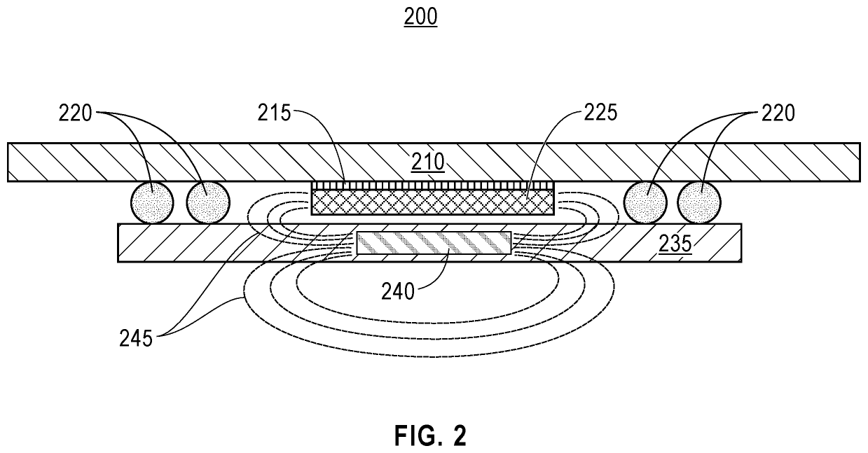

Referring to FIG. 2 there is a pictorial representation (through a cross-sectional view) depicting a second embodiment of a structure 200 consisting of a discrete magnetic shielding sheet 225 between a semiconductor chip 235 and a substrate 210. FIG. 2 depicts a substrate 210 attached to semiconductor chip 235 via one or more solder ball(s) 220. In an embodiment, substrate 210 may be circuit board, mother board, or any other substrate known in the art to connect a semiconductor chip 235. In an embodiment, the substrate 210 may be an organic substrate. In an embodiment, substrate 210 may include the load (not shown) that powers the magnetic device 240. In an embodiment, one or more solder ball(s) 220 are used to attach the semiconductor chip 235 to the substrate 210. In an alternative embodiment, any other connecting structure or device known in the art may be used to connect the semiconductor chip 235 to the substrate 210.

FIG. 2 depicts a semiconductor chip 235 that includes magnetic device 240. In an embodiment, semiconductor chip 235 is a fully integrated power converter semiconductor chip. In an embodiment, semiconductor chip 235 employs an on-chip magnetic device 240. In an embodiment, the on-chip magnetic device 240 may be an on-chip inductor or an on-chip transformer, which composes of on-chip metal windings. In an alternative embodiment, the on-chip magnetic device 240 may be an on-chip inductor or an on-chip transformer, which composes of on-chip metal windings and magnetic cores. In an embodiment, the on-chip magnetic device 240 may be more than one on-chip magnetic device 240. In an embodiment, when a current is passed through the on-chip magnetic device 240 a magnetic field 245 is created. The magnetic field 245 may interact with other devices (not shown) that may or may not be connected to substrate 210.

In a second embodiment, as shown in FIG. 2, a discrete magnetic shield 225 is located between the substrate 210 and semiconductor chip 235. In the second embodiment, the discrete magnetic shield 225 is attached to a first side of substrate 210 using adhesive layer 215. In an embodiment, the adhesive layer 215 and adhesive layer 230 may be an adhesive that is thermal conductive, and non-magnetic and non-electrically conductive. For example, adhesive layer 215 and adhesive layer 230 may be CoolTherm® ME-560 Underfill Encapsulant. In an embodiment, the adhesive layer 215 may be a thermal conductive glue. In an embodiment, the discrete magnetic shield 225 prevents magnetic field 245 from penetrating into substrate 210. In an embodiment, the magnetic shield 225 may be a magnetic core, for example, a magnetic piece made of ferromagnetic metal, such as iron, or ferrimagnetic compounds such as ferrites. In an embodiment, the magnetic shield 225 may be from a machined magnetic material. In an embedment, the discrete magnetic shield 225 may also be called a magnetic shielding sheet. In an embodiment, the magnetic shield 225 may be the same lateral area of the magnetic device 240. In an alternative embodiment, the magnetic shield 225 may be a smaller lateral area of the magnetic device 240. In yet another alternative embodiment, the magnetic shield 225 may be a larger lateral area of the magnetic device 240, for example twice the surface area. In an embodiment, the magnetic shield 225 is smaller in thickness than the one or more solder ball(s) 220. For example, if the one or more solder ball(s) 220 is 75 um height, then the magnetic shield 125 may be 40-50 um thick. In an embodiment, the magnetic shield 225 is thinner than the post-assembly height of the one or more solder ball(s) 220. On an embodiment, the void between semiconductor chip 235 and discrete magnetic shield 225 may be filled by a thermal interface material or thermal conductive glue that is non-magnetic and non-conductive.

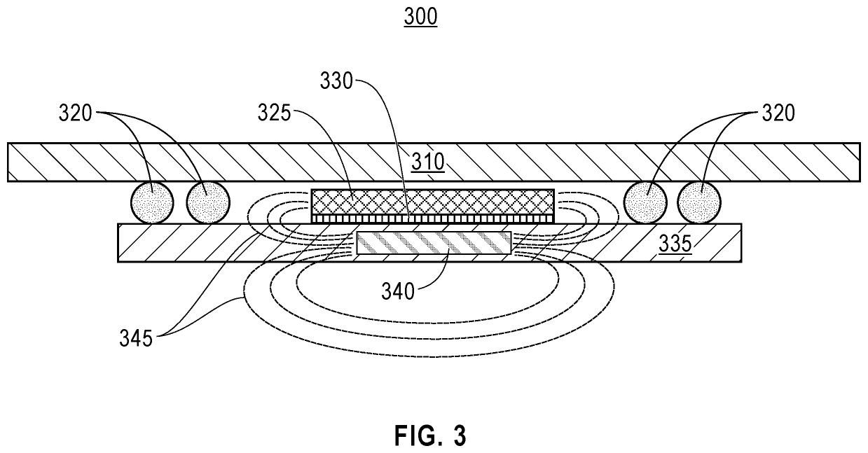

Referring to FIG. 3 there is a pictorial representation (through a cross-sectional view) depicting a third embodiment of a structure 300 consisting of a discrete magnetic shielding sheet 325 between a semiconductor chip 335 and a substrate 310. FIG. 3 depicts a substrate 310 attached to semiconductor chip 335 via one or more solder ball(s) 320. In an embodiment, substrate 310 may be circuit board, mother board, or any other substrate known in the art to connect a semiconductor chip 335. In an embodiment, the substrate 310 may be an organic substrate. In an embodiment, substrate 310 may include the load (not shown) that powers the magnetic device 340. In an embodiment, one or more solder ball(s) 320 are used to attach the semiconductor chip 335 to the substrate 310. In an alternative embodiment, any other connecting structure or device known in the art may be used to connect the semiconductor chip 335 to the substrate 310.

FIG. 3 depicts a semiconductor chip 335 that includes magnetic device 340. In an embodiment, semiconductor chip 335 is a fully integrated power converter semiconductor chip. In an embodiment, semiconductor chip 335 employs an on-chip magnetic device 340. In an embodiment, the on-chip magnetic device 340 may be an on-chip inductor or an on-chip transformer, which composes of on-chip metal windings. In an alternative embodiment, the on-chip magnetic device 340 may be an on-chip inductor or an on-chip transformer, which composes of on-chip metal windings and magnetic cores. In an embodiment, the on-chip magnetic device 340 may be more than one on-chip magnetic device 340. In an embodiment, when a current is passed through the on-chip magnetic device 340 a magnetic field 345 is created. The magnetic field 345 may interact with other devices (not shown) that may or may not be connected to substrate 310.

In a third embodiment, as shown in FIG. 3, a discrete magnetic shield 325 is located between the substrate 310 and semiconductor chip 335. In the third embodiment, the discrete magnetic shield 325 is attached to a first side of the semiconductor chip 335 using adhesive layer 330. In an embodiment, adhesive layer 330 may be an adhesive that is thermal conductive, and non-magnetic and non-electrically conductive. For example, adhesive layer 330 may be CoolTherm® ME-560 Underfill Encapsulant. In an embodiment, the adhesive layer 330 may be a thermal conductive glue. In an embodiment, the discrete magnetic shield 325 prevents magnetic field 345 from penetrating into substrate 310. In an embodiment, the magnetic shield 325 may be a magnetic core, for example, a magnetic piece made of ferromagnetic metal, such as iron, or ferrimagnetic compounds such as ferrites. In an embodiment, the magnetic shield 325 may be from a machined magnetic material. In an embedment, the discrete magnetic shield 325 may also be called a magnetic shielding sheet. In an embodiment, the magnetic shield 325 may be the same lateral area of the magnetic device 340. In an alternative embodiment, the magnetic shield 325 may be a smaller lateral area of the magnetic device 340. In yet another alternative embodiment, the magnetic shield 325 may be a larger lateral area of the magnetic device 340, for example twice the surface area. In an embodiment, the magnetic shield 325 is smaller in thickness than the one or more solder ball(s) 320. For example, if the one or more solder ball(s) 320 is 75 um height, then the magnetic shield 125 may be 40-50 um thick. In an embodiment, the magnetic shield 325 is thinner than the post-assembly height of the one or more solder ball(s) 320. In an embodiment, the void between substrate 310 and discrete magnetic shield 325 may be filled by a thermal interface material or thermal conductive glue that is non-magnetic and non-conductive.

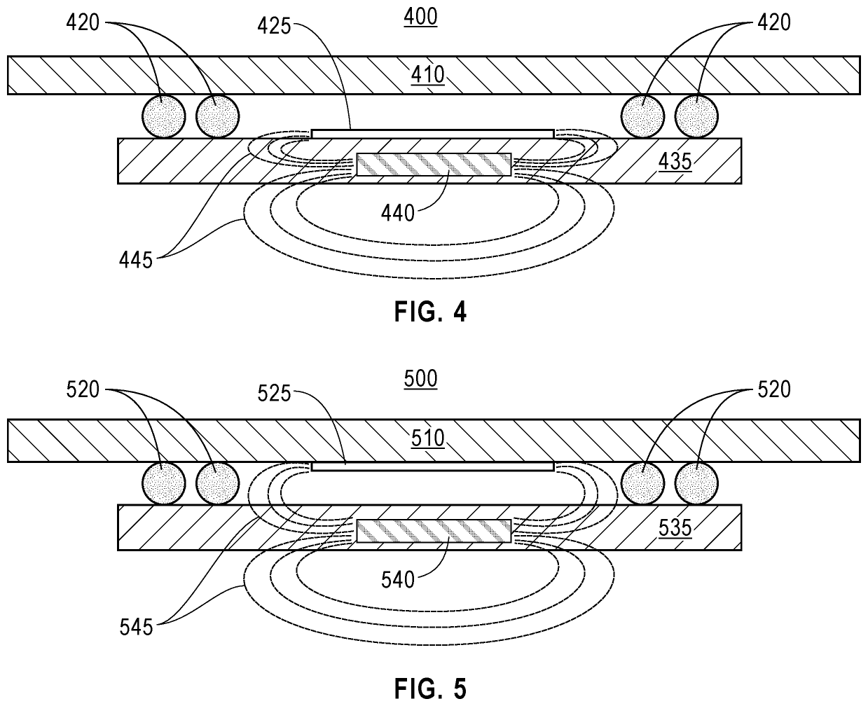

Referring to FIG. 4 there is a pictorial representation (through a cross-sectional view) depicting a fourth embodiment of a structure 400 consisting of a discrete magnetic shielding sheet 425 between a semiconductor chip 435 and a substrate 410. FIG. 4 depicts a substrate 410 attached to a semiconductor chip 435 via one or more solder ball(s) 420. In an embodiment, substrate 410 may be circuit board, mother board, or any other substrate known in the art to connect a semiconductor chip 435. In an embodiment, the substrate 410 may be an organic substrate. In an embodiment, substrate 410 may include the load (not shown) that powers the magnetic device 440. In an embodiment, one or more solder ball(s) 420 are used to attach the semiconductor chip 435 to the substrate 410. In an alternative embodiment, any other connecting structure or device known in the art may be used to connect the semiconductor chip 435 to the substrate 410.

FIG. 4 depicts a semiconductor chip 435 that includes magnetic device 440. In an embodiment, semiconductor chip 435 is a fully integrated power converter semiconductor chip. In an embodiment, semiconductor chip 435 employs an on-chip magnetic device 440. In an embodiment, the on-chip magnetic device 440 may be an on-chip inductor or an on-chip transformer, which composes of on-chip metal windings. In an alternative embodiment, the on-chip magnetic device 440 may be an on-chip inductor or an on-chip transformer, which composes of on-chip metal windings and magnetic cores. In an embodiment, the on-chip magnetic device 440 may be more than one on-chip magnetic device 440. In an embodiment, when a current is passed through the on-chip magnetic device 440 a magnetic field 445 is created. The magnetic field 445 may interact with other devices (not shown) that may or may not be connected to substrate 410.

In a fourth embodiment, as shown in FIG. 4, a discrete magnetic shield 425 is located on semiconductor chip 435. In the fourth embodiment, the discrete magnetic shield 425 is attached directly to semiconductor chip 435. In this embodiment, the discrete magnetic shield 425 may be attached directly to semiconductor chip 435 using any known attaching process in the art. In this embodiment, the discrete magnetic shield 425 may be a ferromagnetic material that is formed by deposition on the semiconductor chip 435. In an alternative embodiment, the discrete magnetic shield 425 may be a thin-film magnetic layer that is attached directly to semiconductor chip 435 using any known attaching process in the art. In an embodiment, the discrete magnetic shield 425 prevents magnetic field 445 from penetrating into substrate 410. In an embodiment, the magnetic shield 425 may be a magnetic core, for example, a magnetic piece made of ferromagnetic metal, such as iron, or ferrimagnetic compounds such as ferrites. In an embodiment, the magnetic shield 425 may be from a machined magnetic material. In an embedment, the discrete magnetic shield 425 may also be called a magnetic shielding sheet. In an embodiment, the magnetic shield 425 may be the same lateral area of the magnetic device 440. In an alternative embodiment, the magnetic shield 425 may be a smaller lateral area of the magnetic device 440. In yet another alternative embodiment, the magnetic shield 425 may be a larger lateral area of the magnetic device 440, for example twice the surface area. In an embodiment, the magnetic shield 425 is 1 um thickness. In an alternative embodiment, the magnetic shield 425 is any thickness optimal needed to disrupt the interference of the magnetic field of the magnetic device 440. In an embodiment, the magnetic shield 425 is thinner than the post-assembly height of the one or more solder ball(s) 420.

Referring to FIG. 5 there is a pictorial representation (through a cross-sectional view) depicting a fifth embodiment of a structure 500 consisting of a discrete magnetic shielding sheet 525 between a semiconductor chip 535 and a substrate 510. FIG. 4 depicts a substrate 510 attached to a semiconductor chip 535 via one or more solder ball(s) 520. In an embodiment, substrate 510 may be circuit board, mother board, or any other substrate known in the art to connect a semiconductor chip 535. In an embodiment, the substrate 510 may be an organic substrate. In an embodiment, substrate 510 may include the load (not shown) that powers the magnetic device 540. In an embodiment, any connecting structure or device known in the art may be used to connect the semiconductor chip 535 to the substrate 510.

FIG. 5 depicts a semiconductor chip 535 that includes magnetic device 540. In an embodiment, semiconductor chip 535 is a fully integrated power converter semiconductor chip. In an embodiment, semiconductor chip 535 employs an on-chip magnetic device 540. In an embodiment, the on-chip magnetic device 540 may be an on-chip inductor or an on-chip transformer, which composes of on-chip metal windings. In an alternative embodiment, the on-chip magnetic device 540 may be an on-chip inductor or an on-chip transformer, which composes of on-chip metal windings and magnetic cores. In an embodiment, when a current is passed through the on-chip magnetic device 540 a magnetic field 545 is created. The magnetic field 545 may interact with other devices (not shown) that may or may not be connected to substrate 510.

In a fifth embodiment, as shown in FIG. 5, a discrete magnetic shield 525 is located on substrate 510. In the fourth embodiment, the discrete magnetic shield 525 is attached directly to substrate 510. In this embodiment, the discrete magnetic shield 525 may be attached directly to substrate 510 using any known attaching process in the art. In this embodiment, the discrete magnetic shield 525 may be a ferromagnetic material that is formed by deposition on the substrate 510. In an alternative embodiment, the discrete magnetic shield 525 may be a thin-film magnetic layer that is attached directly to substrate 510 using any known attaching process in the art. In an embodiment, the discrete magnetic shield 525 prevents magnetic field 545 from penetrating into substrate 510. In an embodiment, the magnetic shield 525 may be a magnetic core, for example, a magnetic piece made of ferromagnetic metal, such as iron, or ferrimagnetic compounds such as ferrites. In an embodiment, the magnetic shield 525 may be from a machined magnetic material. In an embedment, the discrete magnetic shield 525 may also be called a magnetic shielding sheet. In an embodiment, the magnetic shield 525 may be the same lateral area of the magnetic device 540. In an alternative embodiment, the magnetic shield 525 may be a smaller lateral area of the magnetic device 540. In yet another alternative embodiment, the magnetic shield 525 may be a larger lateral area of the magnetic device 540, for example twice the surface area. In an embodiment, the magnetic shield 525 is lum thickness. In an alternative embodiment, the magnetic shield 525 is any thickness optimal needed to disrupt the interference of the magnetic field of the magnetic device 540. In an embodiment, the magnetic shield 525 is thinner than the post-assembly height of the one or more solder ball(s) 520.

1. A structure comprising:
a substrate;
a semiconductor chip connected to the substrate via one or more solder balls; and
a magnetic shielding sheet located between the substrate and the semiconductor chip.

2. The structure of claim 1, wherein the semiconductor chip includes one or more on-chip magnetic devices.

3. The structure of claim 1, wherein the semiconductor chip is a fully integrated power converter.

4. The structure of claim 2, wherein the magnetic shielding sheet has a lateral area that is at least partially the same as the one or more on-chip magnetic devices.

5. The structure of claim 2, wherein the magnetic shielding sheet has a lateral area that is larger than the one or more on-chip magnetic devices.

6. The structure of claim 2, wherein the magnetic shielding sheet covers a footprint of the one or more on-chip magnetic devices.

7. The structure of claim 1, wherein the magnetic shielding sheet is glued to the substrate and the magnetic shielding sheet is glued to the semiconductor chip.

8. The structure of claim 1, wherein the magnetic shielding sheet is glued to the substrate.

9. The structure of claim 1, wherein the magnetic shielding sheet is glued to the semiconductor chip.

10. The structure of claim 7, wherein the glue is a thermal conductive glue that creates a thermal path between the semiconductor chip and the substrate through the magnetic shielding shield.

11. The structure of claim 1, wherein the magnetic shielding sheet is 1 um thickness.

12. The structure of claim 2, wherein the magnetic shielding sheet is twice the surface area of the one or more on-chip magnetic device.

13. The structure of claim 1, wherein the magnetic shielding sheet is thinner than post-assembly height of the one or more solder balls.

14. The structure of claim 1, wherein the magnetic shielding sheet is a machined magnetic material.

15. The structure of claim 1, wherein the magnetic shielding sheet is a ferromagnetic metal.

16. The structure of claim 1, wherein the magnetic shielding sheet is iron.

17. The structure of claim 1, wherein the magnetic shielding sheet is made of ferrimagnetic compounds.

18. The structure of claim 1, wherein the substrate is an organic substrate.

19. The structure of claim 2, wherein current is passed through the one or more on-chip magnetic devices in order to create a magnetic field.

20. The structure of claim 1, wherein the magnetic shielding sheet is between 40 and 50 um thickness.
